(19) United States
(12) Patent Application Publication
(10) Pub. No.: US 2017/0293445 A1
(43) Pub. Date: Oct. 12, 2017

(54) DYNAMIC VOLTAGE REGULATOR SENSING AND REFERENCE VOLTAGE SETTING TECHNIQUES FOR MULTIPLE GATED LOADS

(71) Applicant: Intel Corporation, Santa Clara, CA (US)

(72) Inventors: Amit K. Jain, Portland, OR (US); Sameer Shekhar, Portland, OR (US)

(73) Assignee: Intel Corporation, Santa Clara, CA (US)

(21) Appl. No.: 15/093,687

(22) Filed: Apr. 7, 2016

(51) Int. Cl. G06F 3/06; G06F 1/28; G11C 5/14; G05F 3/02

(52) U.S. Cl. CPC G06F 3/0625; G05F 3/02; G06F 3/0653; G06F 3/0673; G06F 1/28; G11C 5/147

(57) ABSTRACT

Methods and apparatus relating to dynamic voltage regulator sensing and/or reference voltage setting techniques for multiple gated loads are described. In an embodiment, voltage regulator logic is coupled to one or more loads. Each of the one or more loads is in a separate power domain. The voltage regulator logic controls a sensed voltage from the one or more loads in response to a power gate control signal. Other embodiments are also disclosed and claimed.

### FIELD

The present disclosure generally relates to the field of electronics. More particularly, some embodiments relate to dynamic voltage regulator sensing and/or reference voltage setting techniques for multiple gated loads.

### BACKGROUND

Power gating may be utilized to reduce unwanted power consumption due to leakage. More particularly, power gating may shut off the supply of power to circuits that are no longer used. However, implementation of power gating in multiple power domains can be complicated.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIGS. 1 and 7-9 illustrate block diagrams of embodiments of computing systems, which may be utilized to implement various embodiments discussed herein.

FIGS. 2, 3, and 6 illustrate circuit diagrams, according to some embodiments.

FIG. 4 illustrates a timing diagram, according to an embodiment.

FIG. 5 illustrates a table of sample values that may be applied to one or more circuit diagrams discussed herein, according to an embodiment.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

As mentioned above, implementation of power gating in multiple power domains can be complicated. Moreover, some applications may utilize gating of power domains post power conversion in order to reduce leakage power consumption. For these applications, the Voltage Regulator (VR) sense point is generally chosen at a location before the power gate logic and adequate decoupling may be added before the power gating as well to de-sensitize the loop dynamics to the different power gating scenarios. This choice has one or more of the following drawbacks: (1) larger DC (Direct Current) voltage variation (such as DC load line) at the load point or larger voltage guard bands to ensure a requisite minimum voltage; (2) larger voltage droops due to transients on gated domains; and/or (3) higher capacitor cost and more conservative loop design.

To this end, some embodiments relate to dynamic voltage regulator sensing and/or reference voltage setting techniques for multiple gated loads. Various embodiments include sensing schemes that reduce DC load line and/or transient voltage droops for systems with power gated domains. Furthermore, some embodiments provide one or more of: (1) change in sense location based on power gate states; (2) sense voltage determination as a weighted value (e.g., averaging) between domains; (3) transition schemes to go between different power states; and/or (4) changing/setting the reference voltage (sometimes labeled herein as VID) per state. Furthermore, the averaging scheme is one way to provide one or more of the benefits discussed herein. However, embodiments are not limited to averaging and may be done with minimum value of the voltages (or more generally some weighed value) as feedback and not necessarily averaging.

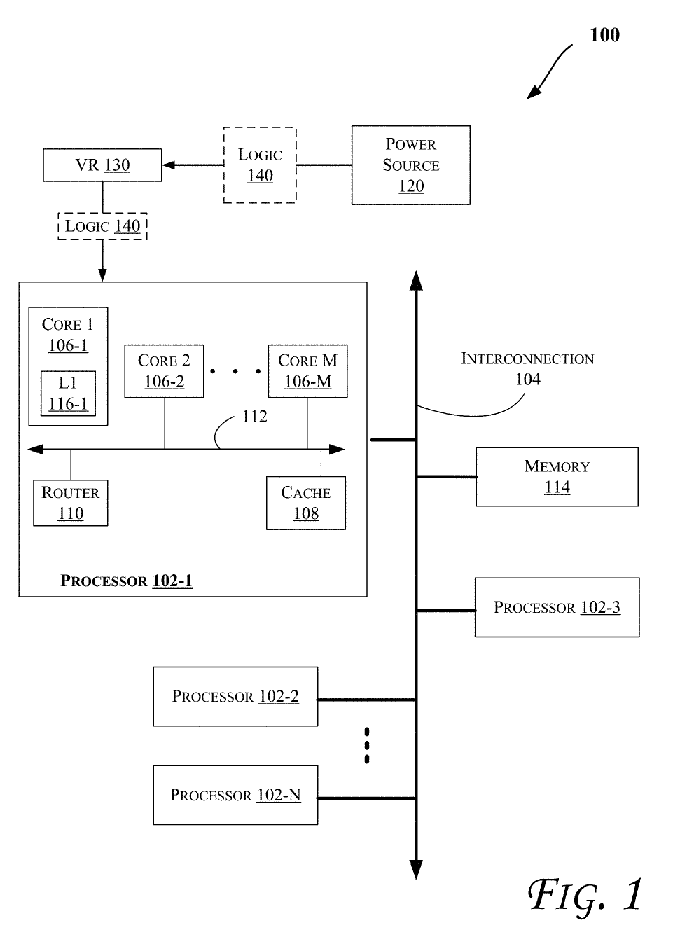

Furthermore, some embodiments may be applied in computing systems that include one or more processors (e.g., with one or more processor cores), such as those discussed with reference to FIGS. 1-9, including for example mobile computing devices (and/or platforms) such as a smartphone, tablet, UMPC (Ultra-Mobile Personal Computer), laptop computer, Ultrabook™ computing device, smart watch, smart glasses, wearable devices, etc., and/or larger systems such as computer servers with many cores, etc. More particularly, FIG. 1 illustrates a block diagram of a computing system 100, according to an embodiment. The system 100 may include one or more processors 102-1 through 102-N (generally referred to herein as “processors 102” or “processor 102”). The processors 102 may communicate via an interconnection or bus 104. Each processor may include various components some of which are only discussed with reference to processor 102-1 for clarity. Accordingly, each of the remaining processors 102-2 through 102-N may include the same or similar components discussed with reference to the processor 102-1.

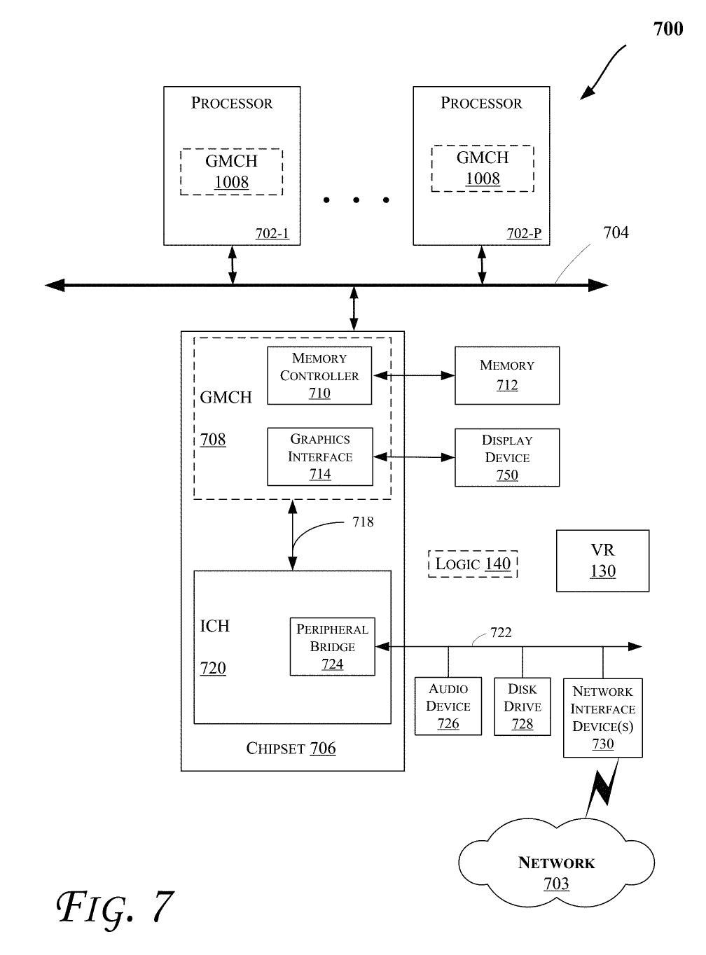

In an embodiment, the processor 102-1 may include one or more processor cores 106-1 through 106-M (referred to herein as “cores 106,” or “core 106”), a cache 108, and/or a router 110. The processor cores 106 may be implemented on a single integrated circuit (IC) chip. Moreover, the chip may include one or more shared and/or private caches (such as cache 108), buses or interconnections (such as a bus or interconnection 112), graphics and/or memory controllers (such as those discussed with reference to FIGS. 7-9), or other components.

In one embodiment, the router 110 may be used to communicate between various components of the processor 102-1 and/or system 100. Moreover, the processor 102-1 may include more than one router 110. Furthermore, the multitude of routers 110 may be in communication to enable data routing between various components inside or outside of the processor 102-1.

The cache 108 may store data (e.g., including instructions) that are utilized by one or more components of the processor 102-1, such as the cores 106. For example, the cache 108 may locally cache data stored in a memory 114 for faster access by the components of the processor 102 (e.g., faster access by cores 106). As shown in FIG. 1, the memory 114 may communicate with the processors 102 via the interconnection 104. In an embodiment, the cache 108 (that may be shared) may be a mid-level cache (MLC), a last level cache (LLC), etc. Also, each of the cores 106 may include a level 1 (L1) cache (116-1) (generally referred to herein as “L1 cache 116”) or other levels of cache such as a level 2 (L2) cache. Moreover, various components of the processor 102-1 may communicate with the cache 108 directly, through a bus (e.g., the bus 112), and/or a memory controller or hub.

The system 100 may also include a platform power source 120 (e.g., a Direct Current (DC) power source or an Alternating Current (AC) power source) to provide power to one or more components of the system 100. The power source 120 could include a PV (Photo Voltaic) panel, wind generator, thermal generator water/hydro turbine, etc. In some embodiments, the power source 120 may include one or more battery packs (e.g., charged by one or more of a PV panel, wind generator, thermal generator water/hydro turbine, plug-in power supply (for example, coupled to an AC power grid), etc.) and/or plug-in power supplies. The power source 120 may be coupled to components of system 100 through a Voltage Regulator (VR) 130. Moreover, even though FIG. 1 illustrates one power source 120 and a single voltage regulator 130, additional power sources and/or voltage regulators may be utilized. For example, one or more of the processors 102 may have corresponding voltage regulator(s) and/or power source(s). Also, the voltage regulator(s) 130 may be coupled to the processor 102 (and/or cores 106) via a single power plane (e.g., supplying power to all the cores 106) or multiple power planes (e.g., where each power plane may supply power to a different core or group of cores).

As discussed herein, various type of voltage regulators may be utilized for the VR 130. For example, VR 130 may include a “buck” VR (which is generally used in power delivery applications in which an input voltage needs to be transformed to an output voltage in a ratio that is smaller than unity) or a “boost” VR (which is generally used in power delivery applications in which an input voltage needs to be transformed to an output voltage in a ratio that is larger than unity), combinations thereof such as a buck-boost VR, etc. Furthermore, in an embodiment, a dual phase, e.g., that may be extendable to multi-phase three-Level buck VR topology.

Additionally, while FIG. 1 illustrates the power source 120 and the voltage regulator 130 as separate components, the power source 120 and the voltage regulator 130 may be incorporated into other components of system 100. For example, all or portions of the VR 130 may be incorporated into the power source 120 and/or processor 102.

As shown in FIG. 1, system 100 may further include logic 140 to provide voltage regulator sensing and/or reference voltage setting techniques for multiple gated loads, e.g., as discussed herein with reference to some embodiments. In an embodiment, logic 140 is provided on a reconfigurable power management ICs (RPMICs), such as a PMIC (Power Management IC) and/or an IMVP (Intel® Mobile Voltage Positioning). Such RPMIC implementation(s) may be used in low power devices (such as portable devices discussed herein) through large computer servers such as discussed herein with reference to FIG. 1 or 7-9.

Moreover, the logic 140 may be coupled to the VR 130 and/or other components of system 100 such as the processor 102 (and/or cores 106) and/or the power source 120. Also, logic 140 may be provide elsewhere in system 100, such as inside the VR 130, inside the processor 102, inside the power source 120, etc.

As mentioned before, various embodiments include sensing schemes that reduce DC load line and/or transient voltage droops for systems with power gated domains. Furthermore, some embodiments provide one or more of: (1) change in sense location based on power gate states; (2) sense voltage determination as a weighted averaging between domains; (3) transition schemes to go between different power states; and/or (4) changing/setting the reference voltage (sometimes labeled herein as VID) per state.

Generally, techniques discussed herein may be used whenever there are multiple gated domains supplied from a single voltage regulator on board, package, or on die. Moreover, embodiments may be designed (a) into a component (e.g., a system on chip with integrated voltage regulation), (b) partly in a voltage regulator by a VR manufacturer, and/or (c) within circuits separate from the voltage regulator and the load chip (or integrated circuit or semiconductor device) by an OEM (Original Equipment Manufacturer).

Additionally, some embodiments provide for one or more of: (1) DC guard band reduction (e.g., without the penalty for increasing maximum voltage); and (2) lower AC guard band reduction (e.g., due to compensation of gated domain parasitics) and more optimal loop design for different power states. Further, these goals may be achieved without addition of passive components or increasing the maximum voltage seen by the loads. Application for processor cores may result in significant improvement in achievable speed and/or power of logic circuits or data interfaces.

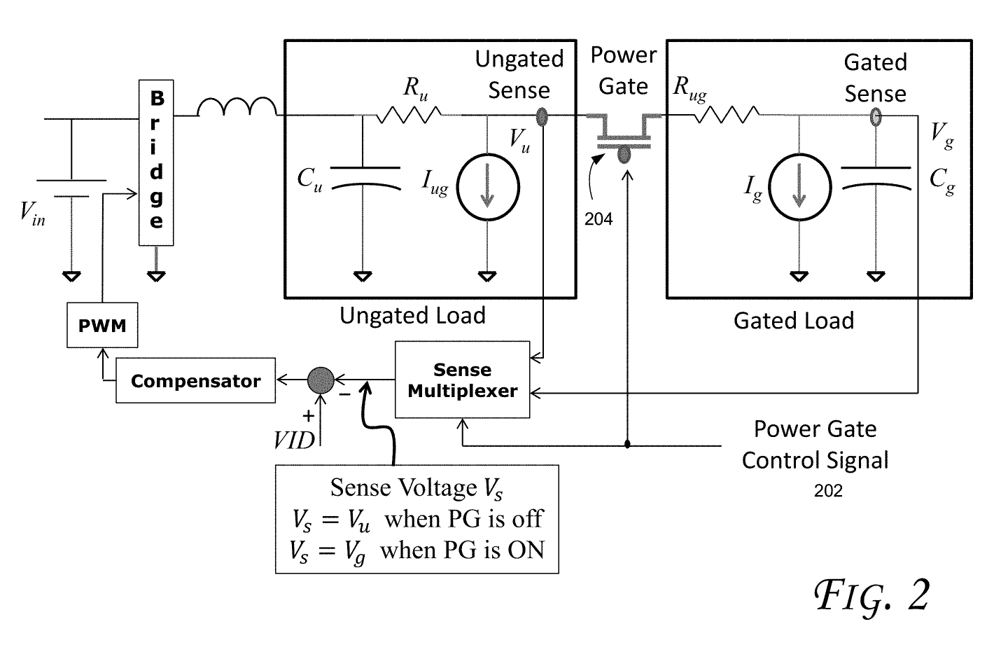

FIG. 2 illustrates a circuit diagram for a sense scheme for a single gated domain, according to an embodiment. More particularly, FIG. 2 depicts designation of sense location/values based on power gate state in a system with ungated loads (that are always connected) and gated loads (that may be turned off at certain times to save/reduce leakage power). This embodiment utilizes the power gate control signal (labeled as PG in the FIGS. 202 to multiplex the sense voltage fed back to the voltage regulator. In an embodiment, logic 140 generates the signal 202. Logic 140 may also include one or more of the sense multiplexer logic, compensator logic, PWM (Pulse Wave Modulator logic, and/or bridge logic in various embodiments. The PWM, bridge, and compensator are integral parts of a power converter, e.g., a buck converter referred earlier: the PWM logic generates PWM signals that go to the bridge which pulse width modulates the input voltage to produce a required output voltage that is regulated to a reference value with negative feedback. The negative feedback loop is stabilized and its response conditioned by the compensator circuit. Also, the power gating may be done by the power gate 204 (e.g., controlled by the signal 202). The power gate 204 may be any type of logic capable of power gating the gated load, such as a transitory. While the illustration shows a buck type regulator, this technique could also be applied for any other type of voltage regulator (such as switched capacitor or linear regulators).

The embodiment shown in FIG. 2 mitigates the DC Load Line (DC LL) for the gated load by effectively mitigating the DC LL contribution from resistance R_{ug} by a factor or (1+GH_{DC}), where GHDc is the DC loop gain of the VR and ΔD_{DCLL} refers to the change in DC LL:

$$DCLL gated = \frac{{R}_{u}}{1 + {GH}_{DC}} + {R}_{ug} \to \frac{{R}_{u} + {R}_{ug}}{1 + {GH}_{DC}}$$

$${Δ}_{DCLL} = {R}_{ug } ( 1 - \frac{1}{1 + {GH}_{DC}} ) ≅ {R}_{ug} for high enough DC gain$$

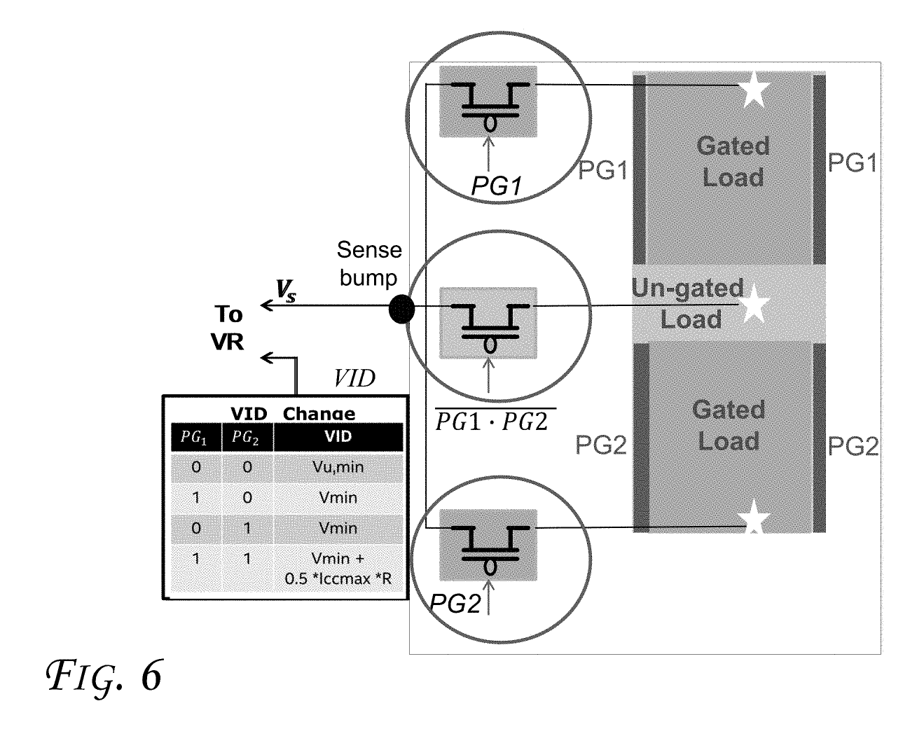

Moreover, for some newer processor cores supplied by a motherboard VR such embodiments may translate to significant clock frequency benefit. For a processor supplied by a Motherboard Voltage Regulator (MBVR), this could be accomplished by introducing a sense point bump (such as discussed with reference to FIG. 6) that provides feedback to the motherboard after multiplexing sense signals coming from the gated and ungated loads based on state of the power gate. Alternatively, three sense signals may be fed back to the VR along with power gating information to accomplish the multiplexing in the VR. In addition, if the VR has fast loop response, it can partially compensate for voltage droop due to impedance between the gated and ungated domains. Transient performance and power gate transitions are discussed below.

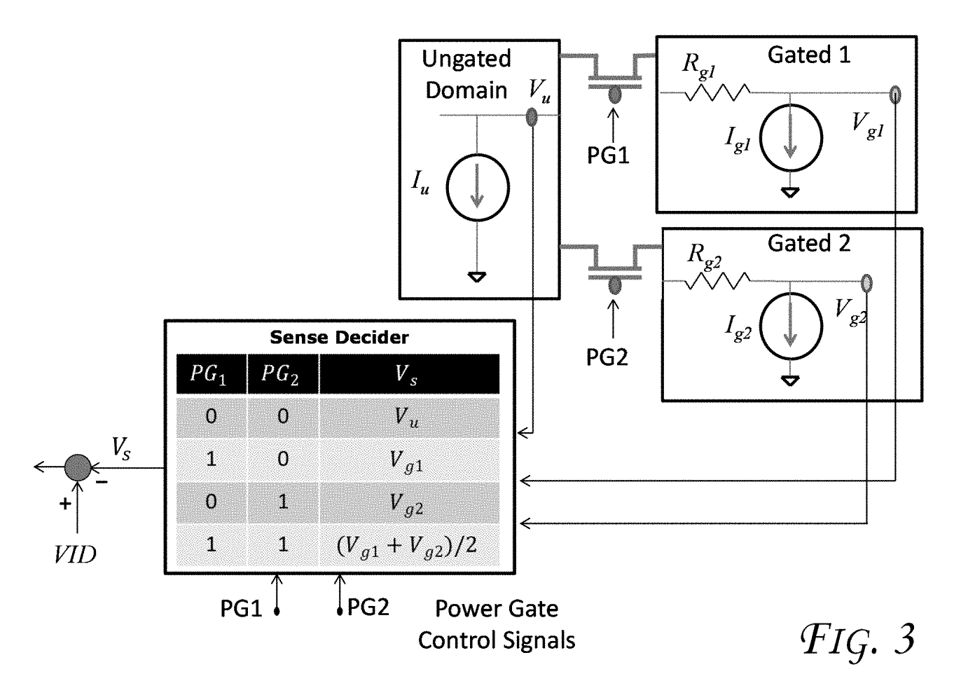

FIG. 3 illustrates a circuit diagram for a sense scheme for multiple gated domains, according to an embodiment. In an embodiment, logic 140 may include the sense decider of FIG. 3. More particularly, the case of one gated domain ON is similar to that described above. With both gated domains power gated on, the sense voltage is determined as

$${V}_{s } = \frac{{V}_{g 1} + {V}_{g 2}}{2} .$$

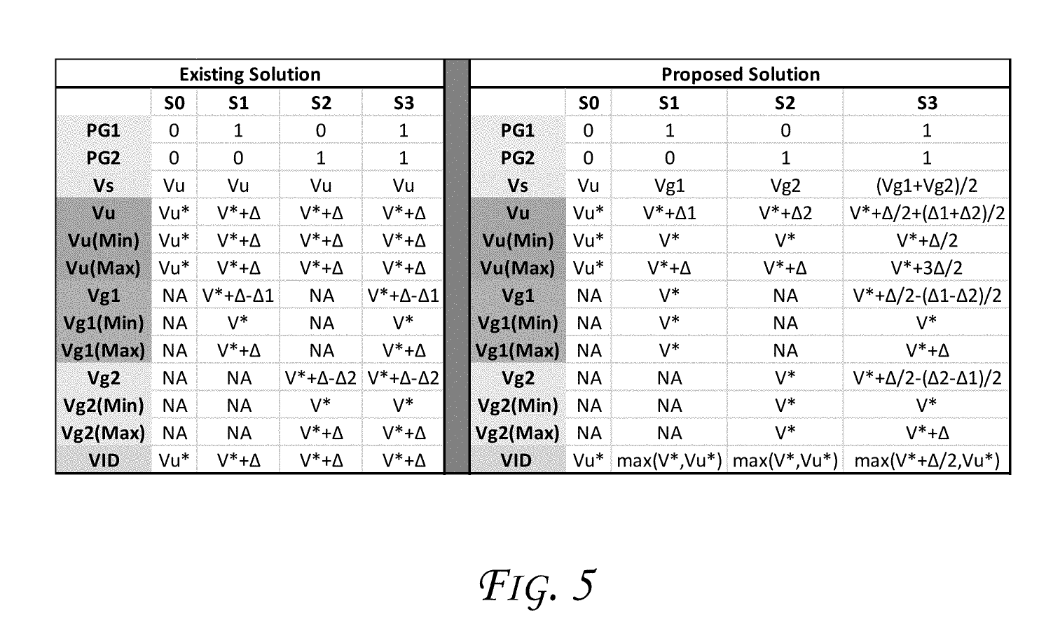

Assuming the VR DC loop gain is high enough, we have:

$${V}_{u} = {V}_{g 1} + {Δ}_{1} = {V}_{g 2} + {Δ}_{2} ;$$

$$and$$

$${V}_{s} = \frac{{V}_{g 1} + {V}_{g 2}}{2} = VID \\ ⇒ {V}_{g 1} = VID + \frac{{Δ}_{2} - {Δ}_{1}}{2} \{ \begin{matrix}min \text{:} VID - \frac{Δ}{2} \\ max \text{:} VID + \frac{Δ}{2}\end{matrix} ; \\ {V}_{g 2} = VID + \frac{{Δ}_{1} - {Δ}_{2}}{2} ; \\ {V}_{u} = VID + \frac{{Δ}_{1} + {Δ}_{2}}{2}$$

where Δ₁=l_{g1}R_{ug1}, Δ₂=I_{g2}R_{ug2}, Δ=max(Δ₁, Δ₂), and VID is the reference voltage for the VR. To guarantee a minimum gated voltage V*, one can set VID=V*+Δ/2. In the case where the sense voltage is fixed to Vᵤ, to guarantee V_{g1}, V_{g2}>V*, we had to set VID=V*+Δ. Thus, the proposed sense scheme of FIG. 3 reduces the DC voltage guard band by Δ/2. Sample detailed comparison of nominal, minimum, and maximum DC voltages are included in the table of FIG. 5, which illustrates a table of sample values that may be applied to one or more circuit diagrams discussed herein, according to an embodiment.

Moreover, FIG. 3 shows the scheme proposed for two gated domains. The sense voltage is the average of all the domains drawing current. For some newer processor cores, the end result derived herein may provide a maximal DC guard band reduction for a single core ON scenario and about half the maximal DC guard band reduction for both cores ON scenario.

This approach may be generalized to multiple gated domains along with current weighted averaging to set the sense voltage as:

$${V}_{s} = {\sum }_{k = 0}^{n} \frac{{PG}_{k} {I}_{k} {V}_{g , k}}{{PG}_{k} {I}_{k}}$$

and determination of a suitable reference voltage that captures variation of domain activity while guaranteeing the minimum required value for all gated and ungated loads. This reference determination could also include characteristics of the power gates such as their resistance and state.

where, PGₖ is the power gate state (1 implying on, 0 implying off), Iₖ is the current of the k^{th} domain, and k=0 refers to the ungated domain. Weighting by domain current provides further improvement by factoring in domain activity. This scheme may be reduced to the two gated domains scenario above by equating I₁ and I₂, and ignoring the current draw on the ungated domain.

As for transient performance, changing the sense point to the gated domain captures the dynamics of the parasitics, decoupling, and the load in the gated domain. There are transient droop benefits by applying the techniques discussed herein. For instance, for an on package VR supplying a processor's ungated load and two gated core domains (called C0 and C1), where the two cores can be power gated on/off independently several benefits are evident. In this example, a baseline (i) has sense point located on ungated domain, C1 and C0 ON, load transient on C0 and leakage on C0, C1, and ungated domain. For a second case (ii), the sense point shifted to C0 with C0 ON, C1 OFF, load transient on C0 and leakage on C0 and ungated domain. For a third case (iii), the sensed voltage is set as Vs=(V_{C0}+V_{C1})/2, with C1 and C0 ON, load transient on C0 and leakage on C0, C1, and the ungated domain.

For the above example, several benefits are evident, including: (A) comparing (ii) with (i), the C0 droop may be reduced by about 2% of its nominal DC value, the C0 voltage may be regulated to the reference value with about 5% DC improvement, and the maximum voltage with overshoot upon load release is almost the same, and (Vₘₐₓ−Vₘᵢₙ) may be the same for C0; and/or (B) comparing (iii) with (i), the droop may be reduced by about 1.5% of nominal DC value, C0 voltage may be regulated to a DC value which is about 3% lower, the maximum C0 voltage with overshoot upon load release is almost the same, and C0 (Vₘₐₓ−Vₘᵢₙ) is lower by 1% of the nominal DC value.

Moreover, in the single core ON scenario, the combined benefit for DC and AC may provide a total guard band reduction of about 7% of nominal DC value without increase in V. on any domain. In the two core scenario, the cumulative guard band reduction may be about 4% of nominal DC value. Furthermore, changing the VR loop compensator R (resistor) and C (capacitor) values with the power gate states to account for extra parasitics along with a change in the sense location can yield even better transient performance for the gated domains, resulting in further guard band reduction. Hence, when the sense point is moved, there is also an AC benefit, e.g., were V_{gi} has reduced activity in (ii) versus (i), which is a transient benefit in addition to the steady state benefits. Generally, the DC benefit is based on VID and sense location change while the AC benefit is due to sense location change regardless of the VID change, due to compensation of transient voltage droop on the gated side

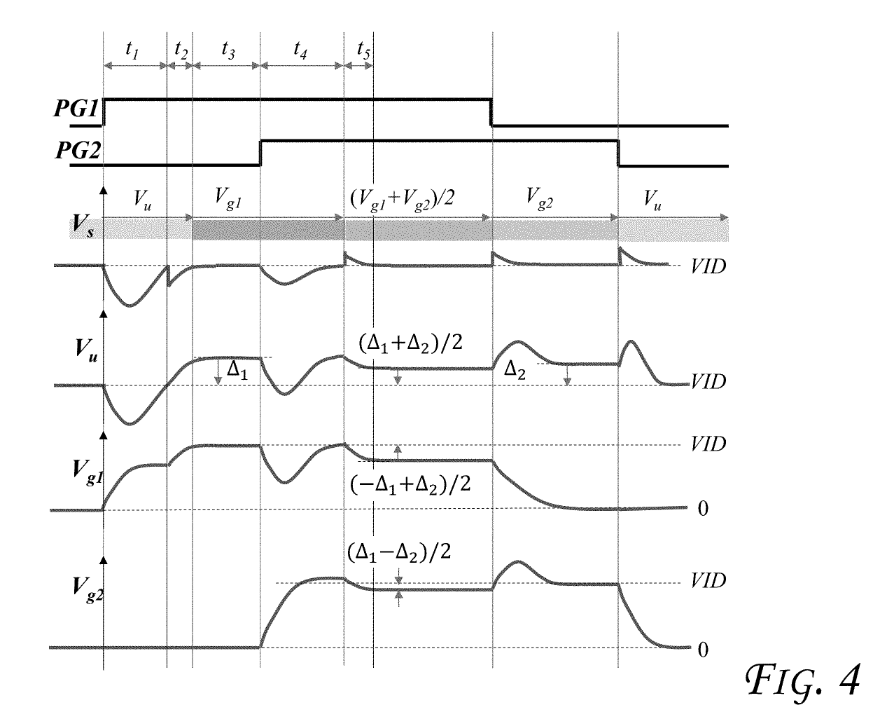

FIG. 4 illustrates a timing diagram of waveforms for a sense voltage transition scheme in two gated domains, according to an embodiment. More particularly, FIG. 4 shows one proposed sense voltage transition schemes as power gate states change in the case of two power gated domains. This technique can be extended to higher number of gated domains. The signals PG1 and PG2 indicate which domains are gated ON, high implying ON and low implying OFF. The sense voltage Vₛ changes with transitions in PG1 and PG2 and are indicated along with delays. The resulting voltage waveforms for the ungated and gated domains are shown.

Referring to FIG. 4, one or more of the following are noted regarding transition of Vₛ:
(a) When the number of domains being supplied increases, (e.g., {PG1, PG2}: {OFF, OFF}→{ON, OFF} or {OFF, ON}→{ON, ON}), the power gate transition is allowed to complete (intervals t₁ and t₄) and only after that Vₛ is changed to reflect the new power gate states. This introduces an additional latency (intervals t₂ and tₛ) for the voltages to settle before the domains can reach their full activity level. These intervals may be lower than typical power state transition times. Both cases present delays that are much smaller than latencies in power gate transitions.

(b) When the number of domains being supplied decreases, (e.g., {PG1, PG2}: {ON, ON} 4 {ON, OFF} or {OFF, ON} 4 {OFF, OFF}), the power gate transition and Vₛ transitions are carried out simultaneously.

Changes in VID not shown in FIG. 4 can be incorporated in the transition scheme.

FIG. 5 illustrates a table of sample values that may be applied to one or more circuit diagrams discussed herein, according to an embodiment. Each column (labeled S0, S1, S2, and S3) refer to different states and corresponding values (shown in the first cell of each row in the table). More particularly, the table of FIG. 5 shows DC voltage comparison between one embodiment and standard ungated sensing. Hence, sample detailed comparison of nominal, minimum, and maximum DC voltages are included in this table in accordance with an embodiment.

Referring to FIG. 5, VID (or reference voltage) is changed with state changes. As shown, the VID value ends up being lower for the proposed solution when compared to the existing solution over time (e.g., for states 51, S2, and S3). For example, for S2, VID is pegged to maximum of (Vu*, V*) (maximum of the absolute minimum voltage required for pre-gate and post gate domains) for the proposed solution. For higher loads, the voltage approaches the existing solution but for lower loads, voltage is lower. Gated domains are in low activity or load more often than high activity; therefore, significant power is saved due to the lower voltage compared to existing solution. Moreover, the proposed solution uses the least voltage to result in power savings during operation.

Accordingly, some embodiments use multiplexer(s), weighted averaging (or more generally a weighed feedback value), or minima determining circuits, setting the reference voltage per state, and/or transition schemes for determining sense voltage for different power gating scenarios. Moreover, at least one embodiment provides guard band reduction in the voltage reference, which directly translates to a power benefit (or a frequency increase at the same power). This will make SoCs implementing such techniques more competitive from power consumption point of view and/or higher frequency. More specifically, (1) for on package VR solutions, such techniques make the solution even more favorable compared to motherboard VR solutions; and/or (2) for some processor products, such techniques may add directly to the frequency benefit.

FIG. 6 illustrates a circuit diagram for a sense scheme for multiple gated domains, according to an embodiment. As described in one embodiment, this circuit does sense selection and averaging, in case of all domains being gated on, depending on the signals PG1 and PG2. In an embodiment, logic 140 may include the VID change logic of FIG. 6. Delay values may be added to the logic signals in FIG. 6, e.g., as illustrated in FIG. 4. While FIG. 6 shows a multiple gated load domains for a CPU die, the circuit may be applied to any multiple gated domain load(s).

FIG. 7 illustrates a block diagram of a computing system 700 in accordance with an embodiment. The computing system 700 may include one or more central processing unit(s) (CPUs) or processors 702-1 through 702-P (which may be referred to herein as “processors 702” or “processor 702”). The processors 702 may communicate via an interconnection network (or bus) 704. The processors 702 may include a general purpose processor, a network processor (that processes data communicated over a computer network 703), or other types of a processor (including a reduced instruction set computer (RISC) processor or a complex instruction set computer (CISC)). Moreover, the processors 702 may have a single or multiple core design. The processors 702 with a multiple core design may integrate different types of processor cores on the same integrated circuit (IC) die. Also, the processors 702 with a multiple core design may be implemented as symmetrical or asymmetrical multiprocessors. In an embodiment, one or more of the processors 702 may be the same or similar to the processors 102 of FIG. 1. In some embodiments, one or more of the processors 702 may include one or more of the cores 106, VR 130, and/or logic 140 of FIG. 1. Also, the operations discussed with reference to FIGS. 1-6 may be performed by one or more components of the system 700. For example, a voltage regulator (such as VR 130 of FIG. 1) may regulate voltage supplied to one or more components of FIG. 7 in conjunction with logic 140.

A chipset 706 may also communicate with the interconnection network 704. The chipset 706 may include a graphics and memory control hub (GMCH) 708. The GMCH 708 may include a memory controller 710 that communicates with a memory 712. The memory 712 may store data, including sequences of instructions that are executed by the processor 702, or any other device included in the computing system 700. In one embodiment, the memory 712 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 704, such as multiple CPUs and/or multiple system memories.

The GMCH 708 may also include a graphics interface 714 that communicates with a display device 750, e.g., a graphics accelerator. In one embodiment, the graphics interface 714 may communicate with the display device 750 via an accelerated graphics port (AGP) or Peripheral Component Interconnect (PCI) (or PCI express (PCIe) interface). In an embodiment, the display device 750 (such as a flat panel display (such as an LCD (Liquid Crystal Display), a cathode ray tube (CRT), a projection screen, etc.) may communicate with the graphics interface 714 through, for example, a signal converter that translates a digital representation of an image stored in a storage device such as video memory or system memory into display signals that are interpreted and displayed by the display. The display signals produced may pass through various control devices before being interpreted by and subsequently displayed on the display device 750.

A hub interface 718 may allow the GMCH 708 and an input/output control hub (ICH) 720 to communicate. The ICH 720 may provide an interface to I/O devices that communicate with the computing system 700. The ICH 720 may communicate with a bus 722 through a peripheral bridge (or controller) 724, such as a peripheral component interconnect (PCI) bridge, a universal serial bus (USB) controller, or other types of peripheral bridges or controllers. The bridge 724 may provide a data path between the processor 702 and peripheral devices. Other types of topologies may be utilized. Also, multiple buses may communicate with the ICH 720, e.g., through multiple bridges or controllers. Moreover, other peripherals in communication with the ICH 720 may include, in various embodiments, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 722 may communicate with an audio device 726, one or more disk drive(s) 728, and one or more network interface device(s) 730 (which is in communication with the computer network 703). Other devices may communicate via the bus 722. Also, various components (such as the network interface device 730) may communicate with the GMCH 708 in some embodiments. In addition, the processor 702 and the GMCH 708 may be combined to form a single chip. Furthermore, the graphics accelerator may be included within the GMCH 708 in other embodiments.

Furthermore, the computing system 700 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 728), a floppy disk, a compact disk ROM (CD-ROM), a digital versatile disk (DVD), flash memory, a magneto-optical disk, or other types of nonvolatile machine-readable media that are capable of storing electronic data (e.g., including instructions). In an embodiment, components of the system 700 may be arranged in a point-to-point (PtP) configuration. For example, processors, memory, and/or input/output devices may be interconnected by a number of point-to-point interfaces.

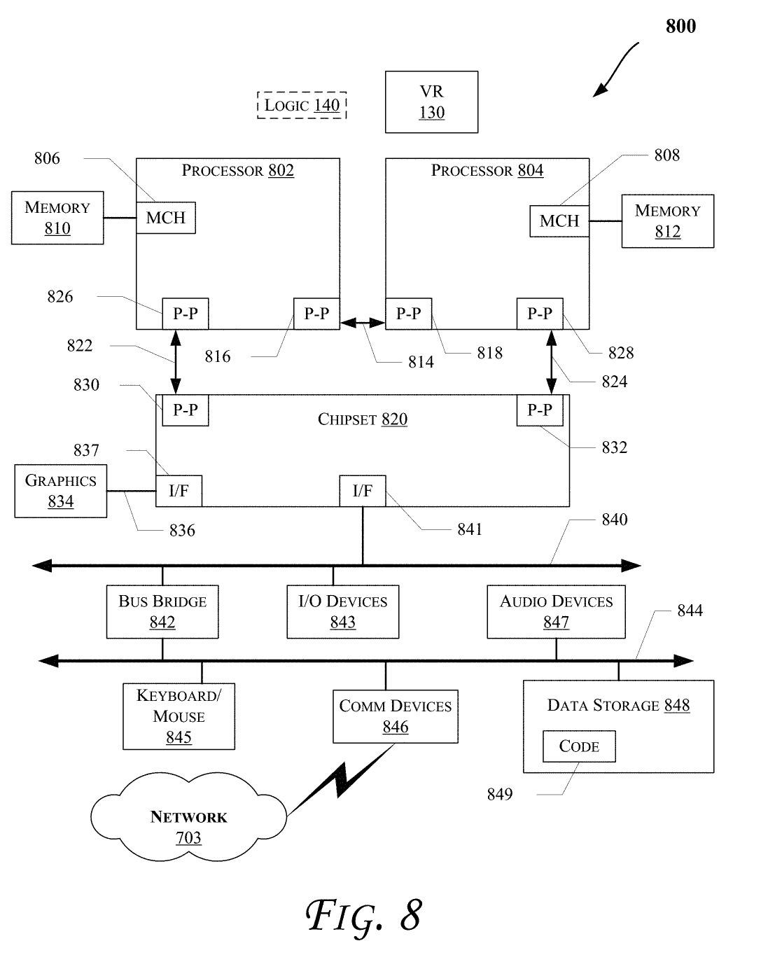

FIG. 8 illustrates a computing system 800 that is arranged in a point-to-point (PtP) configuration, according to an embodiment. In particular, FIG. 8 shows a system where processors, memory, and input/output devices are interconnected by a number of point-to-point interfaces. The operations discussed with reference to FIGS. 1-7 may be performed by one or more components of the system 800. For example, a voltage regulator (such as VR 130 of FIG. 1) may regulate voltage supplied to one or more components of FIG. 8 in conjunction with logic 140.

As illustrated in FIG. 8, the system 800 may include several processors, of which only two, processors 802 and 804 are shown for clarity. The processors 802 and 804 may each include a local memory controller hub (MCH) 806 and 808 to enable communication with memories 810 and 812. The memories 810 and/or 812 may store various data such as those discussed with reference to the memory 712 of FIG. 7. Also, the processors 802 and 804 may include one or more of the cores 106, logic 140, and/or VR 130 of FIG. 1.

In an embodiment, the processors 802 and 804 may be one of the processors 702 discussed with reference to FIG. 7. The processors 802 and 804 may exchange data via a point-to-point (PtP) interface 814 using PtP interface circuits 816 and 818, respectively. Also, the processors 802 and 804 may each exchange data with a chipset 820 via individual PtP interfaces 822 and 824 using point-to-point interface circuits 826, 828, 830, and 832. The chipset 820 may further exchange data with a high-performance graphics circuit 834 via a high-performance graphics interface 836, e.g., using a PtP interface circuit 837.

In at least one embodiment, one or more operations discussed with reference to FIGS. 1-8 may be performed by the processors 802 or 804 and/or other components of the system 800 such as those communicating via a bus 840. Other embodiments, however, may exist in other circuits, logic units, or devices within the system 800 of FIG. 8. Furthermore, some embodiments may be distributed throughout several circuits, logic units, or devices illustrated in FIG. 8.

Chipset 820 may communicate with the bus 840 using a PtP interface circuit 841. The bus 840 may have one or more devices that communicate with it, such as a bus bridge 842 and I/O devices 843. Via a bus 844, the bus bridge 842 may communicate with other devices such as a keyboard/mouse 845, communication devices 846 (such as modems, network interface devices, or other communication devices that may communicate with the computer network 703), audio I/O device, and/or a data storage device 848. The data storage device 848 may store code 849 that may be executed by the processors 802 and/or 804.

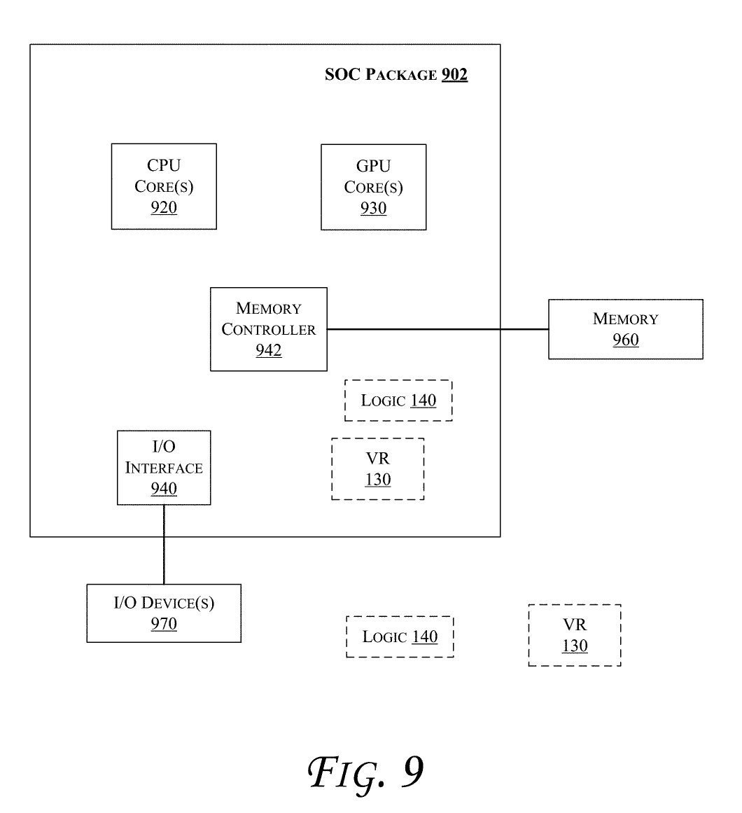

In some embodiments, one or more of the components discussed herein can be embodied as a System On Chip (SOC) device. Also, various embodiments may be provided in:: a multichip SoC, for multi-chip loads on a single package, a single integrated circuit, and/or single package substrate. FIG. 9 illustrates a block diagram of an SOC package in accordance with an embodiment. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 920 may include one or more other components, e.g., as discussed with reference to the other figures herein. In one embodiment, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an embodiment, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like. Furthermore, SOC package 902 may include/integrate the logic 140 and/or VR 130 in an embodiment. Alternatively, the logic 140 and/or VR 130 may be provided outside of the SOC package 902 (i.e., as a discrete logic).

The following examples pertain to further embodiments. Example 1 optionally may include an apparatus comprising: voltage regulator logic, at least a portion of which is in hardware, coupled to one or more loads, wherein each of the one or more loads is in a separate power domain, wherein the voltage regulator logic is to control a sensed voltage from the one or more loads in response to a power gate control signal, wherein the sensed voltage is to be generated in response to a weighed value. Example 2 includes the apparatus of example 1 or any other example discussed herein, wherein the weighed value is to be determined based at least in part on one or more of a weighed current value, a weighed voltage value, and one or more load values. Example 3 includes the apparatus of example 2 or any other example discussed herein, wherein the sensed voltage is to be determined based at least in part on a minima of load voltages. Example 4 includes the apparatus of example 1 or any other example discussed herein, wherein the weighed value is an average weighed value to be determined based at least in part on an average value of one or more of: a current value, a voltage value, and one or more load values. Example 5 includes the apparatus of example 1 or any other example discussed herein, wherein the voltage regulator logic is to determine a reference voltage for the one or more loads. Example 6 includes the apparatus of example 1 or any other example discussed herein, wherein the voltage regulator logic is to modify a reference voltage of a voltage regulator per one or more power gate states. Example 7 includes the apparatus of example 6 or any other example discussed herein, wherein the voltage regulator is to comprise one or more of: a buck voltage regulator logic, a boost voltage regulator logic, a voltage converter logic, a switched capacitor voltage regulator, a linear voltage regulator, or combinations thereof. Example 8 includes the apparatus of example 1 or any other example discussed herein, wherein the voltage regulator logic is to comprise a multi-phase voltage regulator logic. Example 9 includes the apparatus of example 1 or any other example discussed herein, wherein the voltage regulator logic is to comprise one or more of: multiplexer logic, compensator logic, pulse wave modulation logic, or bridge logic. Example 10 includes the apparatus of example 1 or any other example discussed herein, wherein the voltage regulator logic is to mitigate Direct Current (DC) or Alternating Current (AC) Load Line (LL) for the one or more loads. Example 11 includes the apparatus of example 1 or any other example discussed herein, wherein the voltage regulator logic is to be coupled to at least one ungated load. Example 12 includes the apparatus of example 1 or any other example discussed herein, wherein one or more of: the voltage regulator logic, a processor having one or more processor cores, a voltage regulator, and memory are on a single integrated circuit.

Example 13 optionally may include a computing system comprising: memory to store data; a processor, coupled to the memory, to perform one or more operations on the stored data; and voltage regulator logic, at least a portion of which is in hardware, coupled to one or more loads, wherein each of the one or more loads is in a separate power domain, wherein the voltage regulator logic is to control a sensed voltage from the one or more loads in response to a power gate control signal, wherein the sensed voltage is to be generated in response to a weighed value. Example 14 includes the system of example 13 or any other example discussed herein, wherein the weighed value is to be determined based at least in part on one or more of a weighed current value, a weighed voltage value, and one or more load values. Example 15 includes the system of example 13 or any other example discussed herein, wherein the weighed value is an average weighed value to be determined based at least in part on an average value of one or more of: a current value, a voltage value, and one or more load values. Example 16 includes the system of example 13 or any other example discussed herein, wherein the voltage regulator logic is to determine a reference voltage for the one or more loads. Example 17 includes the system of example 13 or any other example discussed herein, wherein the voltage regulator logic is to modify a reference voltage of a voltage regulator per one or more power gate states. Example 18 includes the system of example 17 or any other example discussed herein, wherein the voltage regulator is to comprise one or more of: a buck voltage regulator logic, a boost voltage regulator logic, a voltage converter logic, a switched capacitor voltage regulator, a linear voltage regulator, or combinations thereof. Example 19 includes the system of example 13 or any other example discussed herein, wherein the voltage regulator logic is to comprise a multi-phase voltage regulator logic. Example 20 includes the system of example 13 or any other example discussed herein, wherein the voltage regulator logic is to comprise one or more of: multiplexer logic, compensator logic, pulse wave modulation logic, or bridge logic. Example 21 includes the system of example 13 or any other example discussed herein, wherein the voltage regulator logic is to be coupled to at least one ungated load. Example 22 includes the system of example 13 or any other example discussed herein, wherein one or more of: the voltage regulator logic, the processor having one or more processor cores, a voltage regulator, and the memory are on a single integrated circuit.

Example 23 includes one or more computer-readable medium comprising one or more instructions that when executed on at least one processor configure the at least one processor to perform one or more operations to: control a sensed voltage from one or more loads in response to a power gate control signal, wherein each of the one or more loads is in a separate power domain, wherein the sensed voltage is to be generated in response to a weighed value. Example 24 includes the computer-readable medium of example 23 or any other example discussed herein, further comprising one or more instructions that when executed on the at least one processor configure the at least one processor to perform one or more operations to determine the weighed value based at least in part on one or more of a weighed current value, a weighed voltage value, and one or more load values. Example 25 includes the computer-readable medium of example 23 or any other example discussed herein, wherein the weighed value is an average weighed value to be determined based at least in part on an average value of one or more of: a current value, a voltage value, and one or more load values.

Example 26 optionally may include an apparatus comprising means to perform a method as set forth in any preceding example. Example 27 comprises machine-readable storage including machine-readable instructions, when executed, to implement a method or realize an apparatus as set forth in any preceding example.

In various embodiments, the operations discussed herein, e.g., with reference to FIGS. 1-9, may be implemented as hardware (e.g., logic circuitry), software, firmware, or combinations thereof, which may be provided as a computer program product, e.g., including a tangible machine-readable or computer-readable medium having stored thereon instructions (or software procedures) used to program a computer to perform a process discussed herein. The machine-readable medium may include a storage device such as those discussed with respect to FIGS. 1-9.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
voltage regulator logic, at least a portion of which is in hardware, coupled to one or more loads, wherein each of the one or more loads is in a separate power domain,
wherein the voltage regulator logic is to control a sensed voltage from the one or more loads in response to a power gate control signal, wherein the sensed voltage is to be generated in response to a weighed value.

2. The apparatus of claim 1, wherein the weighed value is to be determined based at least in part on one or more of a weighed current value, a weighed voltage value, and one or more load values.

3. The apparatus of claim 2, wherein the sensed voltage is to be determined based at least in part on a minima of load voltages.

4. The apparatus of claim 1, wherein the weighed value is an average weighed value to be determined based at least in part on an average value of one or more of: a current value, a voltage value, and one or more load values.

5. The apparatus of claim 1, wherein the voltage regulator logic is to determine a reference voltage for the one or more loads.

6. The apparatus of claim 1, wherein the voltage regulator logic is to modify a reference voltage of a voltage regulator per one or more power gate states.

7. The apparatus of claim 6, wherein the voltage regulator is to comprise one or more of: a buck voltage regulator logic, a boost voltage regulator logic, a voltage converter logic, a switched capacitor voltage regulator, a linear voltage regulator, or combinations thereof.

8. The apparatus of claim 1, wherein the voltage regulator logic is to comprise a multi-phase voltage regulator logic.

9. The apparatus of claim 1, wherein the voltage regulator logic is to comprise one or more of: multiplexer logic, compensator logic, pulse wave modulation logic, or bridge logic.

10. The apparatus of claim 1, wherein the voltage regulator logic is to mitigate Direct Current (DC) or Alternating Current (AC) Load Line (LL) for the one or more loads.

11. The apparatus of claim 1, wherein the voltage regulator logic is to be coupled to at least one ungated load.

12. The apparatus of claim 1, wherein one or more of: the voltage regulator logic, a processor having one or more processor cores, a voltage regulator, and memory are on a single integrated circuit.

13. A computing system comprising:
memory to store data;
a processor, coupled to the memory, to perform one or more operations on the stored data; and
voltage regulator logic, at least a portion of which is in hardware, coupled to one or more loads, wherein each of the one or more loads is in a separate power domain,
wherein the voltage regulator logic is to control a sensed voltage from the one or more loads in response to a power gate control signal, wherein the sensed voltage is to be generated in response to a weighed value.

14. The system of claim 13, wherein the weighed value is to be determined based at least in part on one or more of a weighed current value, a weighed voltage value, and one or more load values.

15. The system of claim 13, wherein the weighed value is an average weighed value to be determined based at least in part on an average value of one or more of: a current value, a voltage value, and one or more load values.

16. The system of claim 13, wherein the voltage regulator logic is to determine a reference voltage for the one or more loads.

17. The system of claim 13, wherein the voltage regulator logic is to modify a reference voltage of a voltage regulator per one or more power gate states.

18. The system of claim 17, wherein the voltage regulator is to comprise one or more of: a buck voltage regulator logic, a boost voltage regulator logic, a voltage converter logic, a switched capacitor voltage regulator, a linear voltage regulator, or combinations thereof.

19. The system of claim 13, wherein the voltage regulator logic is to comprise a multi-phase voltage regulator logic.

20. The system of claim 13, wherein the voltage regulator logic is to comprise one or more of: multiplexer logic, compensator logic, pulse wave modulation logic, or bridge logic.

21. The system of claim 13, wherein the voltage regulator logic is to be coupled to at least one ungated load.

22. The system of claim 13, wherein one or more of: the voltage regulator logic, the processor having one or more processor cores, a voltage regulator, and the memory are on a single integrated circuit.

23. One or more computer-readable medium comprising one or more instructions that when executed on at least one processor configure the at least one processor to perform one or more operations to:
control a sensed voltage from one or more loads in response to a power gate control signal, wherein each of the one or more loads is in a separate power domain,
wherein the sensed voltage is to be generated in response to a weighed value.

24. The computer-readable medium of claim 23, further comprising one or more instructions that when executed on the at least one processor configure the at least one processor to perform one or more operations to determine the weighed value based at least in part on one or more of a weighed current value, a weighed voltage value, and one or more load values.

25. The computer-readable medium of claim 23, wherein the weighed value is an average weighed value to be determined based at least in part on an average value of one or more of: a current value, a voltage value, and one or more load values.
